(19) United States
(12) Patent Application Publication
(10) Pub. No.: US 2009/0052225 A1
(43) Pub. Date: Feb. 26, 2009

(54) Nonvolatile Semiconductor Memory Device

(76) Inventor: Hidenori Morimoto, Nara (JP)

Correspondence Address: NIXON & VANDERHYE, PC, 901 NORTH GLEBE ROAD, 11TH FLOOR, ARLINGTON, VA, 22203, US

(21) Appl. No.: 11/795,820

(22) PCT Filed: Jan. 5, 2006
(86) PCT No.: PCT/JP06/00040

§ 371 Date: Apr. 14, 2008

(30) Foreign Application Priority Data
Jan. 24, 2005 (JP) 2005-015108

(51) Int. Cl. G11C 11/00; G11C 11/416

(52) U.S. Cl. 365/148; 365/189.011

(57) ABSTRACT

A nonvolatile semiconductor memory device capable of suppressing parasitic currents in unselected memory cells, in cross-point array including memory cells comprising a two-terminal circuit having a variable resistor storing information according to electric resistance change due to electric stress. The memory cell comprises a series circuit of the variable resistive element holding a variable resistor between an upper and lower electrodes, and the two-terminal element having non-linear current-voltage characteristics making currents flow bi-directionally. The two-terminal element has a switching characteristic that currents bi-directionally flow according to polarity of a voltage applied to both ends when an absolute voltage value exceeds a certain value, and currents larger than predetermined minute currents do not flow when the absolute value is the certain value or less, and can make currents whose current density is 30 kA/cm² or more flow regularly when a predetermined high voltage whose absolute value exceeds the certain value is applied.

### CROSS-REFERENCE TO RELATED APPLICATIONS

This application is a National Phase filing under 35 U.S.C. § 371 of International Application No. PCT/JP2006/300040 filed on Jan. 5, 2006, and which claims priority to Japanese Patent Application No. 2005-015108 filed on Jan. 24, 2005.

### TECHNICAL FIELD

The present invention relates to a nonvolatile semiconductor memory device, and more specifically relates to the nonvolatile semiconductor memory device provided with a memory cell array, with a plurality of memory cells arranged in a row direction and in a column direction, which are constituted of a two-terminal circuit having a variable resistor for storing information in accordance with the change of an electric resistance due to electric stress.

### BACKGROUND ART

In recent years, the nonvolatile semiconductor memory device using a variable resistive element typically exemplified by a magnetic random access memory (MRAM) and a phase change memory has been actively developed. Among them, RRAM (Resistive RAM) disclosed in a non-patent document 1 as will be described below has an extremely small power consumption, capable of easily realizing finer and higher integration, and has a significantly larger dynamic range of change of resistance compared to the MRAM, thus having a possibility of a multilevel storing and attracts attention.

In order to put the nonvolatile semiconductor memory device using such a variable resistive element in practical use, there has been mainly proposed architectures (constitutional methods) of three memory cell arrays heretofore.

A first architecture is one of so-called cross-point type arrays, wherein a memory cell composed of only variable resistive element is individually directly inserted between a bit line and a word line of each intersectional region of a plurality of bit lines arranged in parallel and a plurality of word lines arranged perpendicularly to these bit lines. In this architecture, there is no switching element such as a transistor in each memory cell, thereby making it possible to constitute the memory cell array in which a plurality of layers are easily vertically laminated. Therefore, it is possible to realize the memory cell array with extremely high integration of an order of 4F²/N (F: minimum working dimensions, N: the number of laminations).

In the cross-point type array of this architecture, there is no switching element in the memory cells, and therefore there is a problem that large parasitic currents flow through unselected memory cells, depending on a resistance state corresponded to a storage state of the unselected memory cells, and such parasitic currents are superposed on reading currents that flow through selected memory cells, thus making it difficult or impossible to discriminate the reading currents. Here, when a size of the memory cell array is large, the number of the unselected memory cells is increased, and an influence of the parasitic currents becomes further remarkable. Therefore, as is disclosed in a non-patent document 2 as will be described below, in order to maintain the aforementioned parasitic currents small in a large memory cell array, a resistance value of the variable resistive element of each memory cell must be set extremely high. However, when the resistance value of the variable resistive element is high, there is a problem that the reading currents that flow through selected memory cells also become smaller, thus making reading action much slower and deteriorating an operation margin at the time of reading.

A second architecture is a case that the memory cell is a so-called 1T1R type memory cell constituted by connecting the transistor that functions as a three-terminal switching element and the variable resistive element in series. Since the currents that flow through unselected memory cells are completely interrupted by the transistor, a high speed access is possible, whereby the aforementioned parasitic currents are substantially removed. However, in the 1T1R type memory cell, at least 8F² (F: minimum working dimensions) or a memory cell size larger than 8F² is required. In this case, in order to form the transistor in one memory cell region, one silicon surface is necessary. This makes it impossible to perform lamination of the memory cells, thus posing a problem in the point of high-density.

A third architecture is the architecture of a so-called 1D1R type memory cell as another form of the cross-point array having combined merits of the aforementioned two architectures, wherein the memory cells having the variable resistive element and a thin film diode connected in series, are individually directly inserted between the bit line and the word line of each intersectional region of a plurality of bit lines arranged in parallel and a plurality of word lines arranged perpendicularly to these bit lines. As the diode connected to the variable resistive element in series, a PN diode and a Schottky diode are generally used. Since the parasitic currents are not flown due to an existence of the diode, the high speed access is possible, and the working dimensions of the variable resistive element and the diode can be set at the same value, thus realizing a high-density state in the same way as the first architecture.

However, in the third architecture, the currents can be flown only in one direction, due to the existence of the diode. Therefore, in a case of the variable resistive element such as a RRAM whereby writing (programming and erasing) is performed by flowing currents bi-directionally, storage data can not be erased. In order to solve this problem, as is disclosed in the following patent document 1, by using a MIM (Metal-Insulator-Metal) tunnel diode as the diode, bi-directional currents can be controlled. In addition, in this patent document 1, as another form of enabling the bi-directional currents to be controlled, there is proposed a structure in which two diodes are connected in series or in parallel so that two diodes may be series with the variable resistive element.

Patent document 1: U.S. Pat. No. 6,753,561

Non-patent document 1: W. W. Zhuang, et al. “Novel Colossal Magnetoresistive Thin Film Nonvolatile Resistance Random Access Memory (RRAM)”, IEDM Tech. Dig, pp. 193 to 196, 2002.

Non-patent document 2: N. Sakimura, et al. “A 512k Cross-Point Cell MRAM”, ISSCC Digest of Technical Papers, pp. 130 to 131, 2003.

### DISCLOSURE OF THE INVENTION

### Problems to be Solved by the Invention

However, in the aforementioned third architecture, as is disclosed in the following patent document 1, when the MIM tunnel diode is used as the diode, the MIM tunnel diode generally needs to use an extremely thin insulating film of 10 nm or less as the tunnel insulating film, so as to be operated at a low voltage. Therefore, when a current density necessary for writing is large, there is a risk of destroying the tunnel insulating film. In a case of the RRAM disclosed in the non-patent document 1, the current density for programming is 30 kA/cm² or more, which is larger by 4 digits than 1 mA/cm² to 1 A/cm² generally used in a constant current stress test of an oxide film of a MOS transistor, thus posing a problem in reliability of the tunnel insulating film and an upper limit of the number of writings is limited to a small value. Moreover, in the structure in which two diodes are connected in series or in parallel so as to be series with the variable resistive element, a circuit structure of the memory cell is complicated and this structure is not practical.

In view of the above-described problem of the third architecture, the present invention is provided, and an object of the present invention is to provide the nonvolatile semiconductor memory device capable of controlling the bi-directional currents and capable of suppressing the parasitic currents that flow through the unselected memory cells, in the cross-point type array structure provided with the memory cells constituted of a two-terminal circuit having a variable resistor for storing information in accordance with the change of the electric resistance due to electric stress.

### Means for Solving the Problems

In order to achieve the aforementioned object, the nonvolatile semiconductor memory device of the present invention is the nonvolatile semiconductor memory device comprising a memory cell array with a plurality of memory cells arranged in a row direction and in a column direction, each of the memory cells comprising a two-terminal circuit having a variable resistor for storing information in accordance with the change of an electric resistance due to electric stress, wherein the memory cells have switching characteristics that currents bi-directionally flow according to the voltage polarity of the voltage applied to both ends of the memory cells when the absolute value of the voltage exceeds a certain value, and currents larger than predetermined minute currents do not flow when the absolute value of the applied voltage is the certain value or less, and can make currents whose current density is 30 kA/cm² or more flow regularly when a predetermined high voltage whose absolute value exceeds the certain value is applied.

Further, according to the nonvolatile semiconductor memory device of the present invention, the memory cell comprises a variable resistive element in which a variable resistor is held between an upper electrode and a lower electrode, and a two-terminal element connected to the variable resistive element in series and having non-linear current-voltage characteristics allowing currents to flow bi-directionally, wherein the two-terminal element has switching characteristics that currents bi-directionally flow according to the voltage polarity of the voltage applied to both ends of the two-terminal element when the absolute value of the voltage exceeds a certain value, and currents larger than predetermined minute currents do not flow when the absolute value of the applied voltage is the certain value or less, and can make currents whose current density is 30 kA/cm² or more flow regularly when a predetermined high voltage whose absolute value exceeds the certain value is applied.

Further, according to the nonvolatile semiconductor memory device of the present invention, the two-terminal element is a varistor.

Further, according to the nonvolatile semiconductor memory device of the present invention, the two-terminal element is mainly composed of zinc oxide or SrTiO₃.

Further, according to the nonvolatile semiconductor memory device of the present invention, the lower electrode of the plurality of memory cells arranged in the same row is connected to a common word line, the upper electrode of the plurality of memory cells arranged in the same column is connected to a common bit line in the memory cell array, and there are provided at least a control circuit for controlling programming, erasing, and reading of information into/from the memory cell; a voltage switch circuit for switching a programming voltage, an erasing voltage, and a reading voltage to be applied to the word line and the bit line; and a reading circuit for reading the information from the memory cell.

Further, according to the nonvolatile semiconductor storage device of the present invention, the polarity of the voltage applied to the memory cell is inverted in programming and in erasing.

Further, according to the nonvolatile semiconductor memory device of the present invention, the variable resistor is a metal oxide having a perovskite type crystalline structure.

Further, according to the nonvolatile semiconductor memory device of the present invention, the variable resistor is a metal oxide expressed by a general formula, Pr₁₋ₓCaₓMnO₃ (X=0.3, 0.5).

### BRIEF DESCRIPTION OF THE DRAWINGS

FIG. 1 is a block diagram showing an overall rough structure of an embodiment of a nonvolatile semiconductor memory device of the present invention.

FIG. 2 is a perspective view schematically showing a three-dimensional structure of a memory cell array of the nonvolatile semiconductor memory device of the present invention.

FIG. 3 is a sectional view of a section parallel to a direction of the bit line, schematically showing the structure of the memory cell array of the nonvolatile semiconductor memory device of the present invention.

FIG. 4 is a view of a current-voltage characteristic showing non-linear current-voltage characteristics used in the nonvolatile semiconductor memory device of the present invention.

FIG. 5 is a plan view showing an example of the memory cell array of the nonvolatile semiconductor memory device of the present invention.

FIG. 6 is a current-voltage characteristic view showing the current-voltage characteristics of the memory cell of the nonvolatile semiconductor memory device of the present invention.

FIG. 7 is a current-voltage characteristic view showing the current-voltage characteristics of the memory cell of the nonvolatile semiconductor memory device of the present invention.

### DESCRIPTION OF NUMERALS

100: Nonvolatile semiconductor memory device of the present invention
101: Memory cell array
102: Address line
103: Data line
104: Word line decoder
105: Bit line decoder
106: Control circuit
107: Reading circuit
108: Voltage switch circuit
109: Control signal line
200: Memory cell array
210: Bit line
220: Word line
230: Variable resistor
240: Upper electrode
250: Lower electrode
260: Variable resistive element
270: Non-linear element (two-terminal element)
280: Memory cell
BL0 to BL3: Bit lines
WL0 to WL3: Word lines
M00 to M33: Memory cells

### BEST MODE FOR CARRYING OUT THE INVENTION

Preferred embodiments of a nonvolatile semiconductor memory device (referred to as “a device of the present invention” as needed) according to the present invention and a control method of the same will be explained with reference to the drawings.

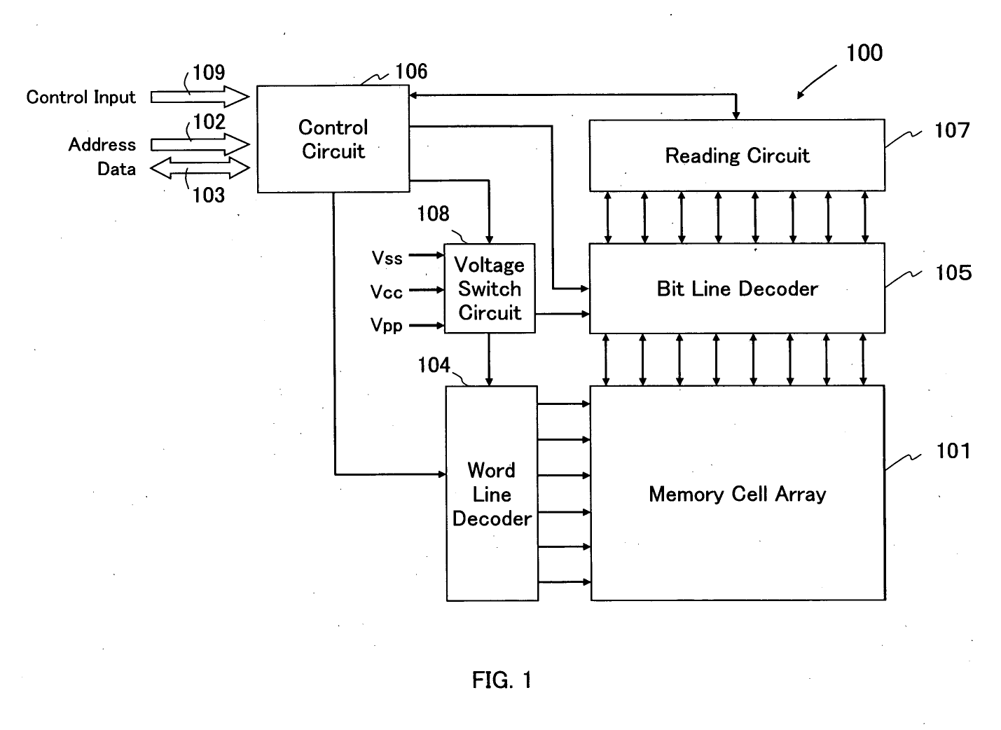

FIG. 1 shows a block diagram of a device 100 of the present invention. In the device 100 of the present invention, information is stored in a memory cell array 101, with a plurality of memory cells arranged in a row direction and in a columnar direction respectively, making it possible to read the information stored in each memory cell in the memory cell array 101.

The information is stored in a particular memory cell in the memory cell array 101 corresponding to an address inputted from an address line 102, and this information passes through a data line 103 and is outputted to an external device. A word line decoder 104 selects a word line of the memory cell array 101 corresponding to a signal inputted in the address line 102, and a bit line decoder 105 selects a bit line of the memory cell array 101 corresponding to an address signal inputted in the address line 102.

A control circuit 106 performs control of programming, erasing, and reading in/from the memory cell array 101. The control circuit 106 controls the word line decoder 104, the bit line decoder 105, and a voltage switch circuit 108, based on the address signal inputted from the address line 102, data input (at the time of programming) inputted from the data line 103, and a control input signal inputted from a control signal line 109, to thereby control reading, programming, and erasing actions in/from the memory cell array 101. In an example as shown in FIG. 1, the control circuit 106 has a function as a general address buffer circuit, a data input/output buffer circuit, and a control input buffer circuit (not shown).

The voltage switch circuit 108 supplies a voltage of the bit line and the word line necessary for reading, programming, and erasing in/from the memory cell array 101. Vcc indicates a supply voltage of a device, Vss indicates a ground voltage, and Vpp indicates the voltage for programming or erasing.

Reading of data is performed by passing through the memory cell array 101, the bit line decoder 105, and the reading circuit 107. The reading circuit 107 judges a state of data, sends its result to the control circuit 106, and outputs it to the data line 103.

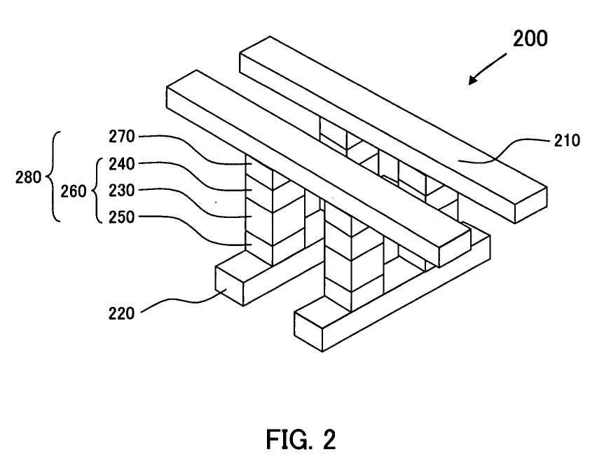

FIG. 2 schematically shows a three-dimensional structure of the memory cell array. In FIG. 2, for convenience of explanation, a memory cell array 200 of 2×2 structure is shown as an example. The memory cell array 200 is constituted, with memory cells 280 held between intersecting points of two bit lines 210 and two word lines 220.

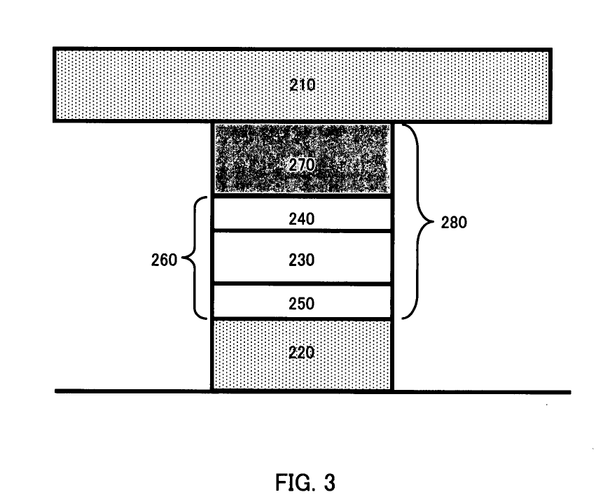

FIG. 3 shows a sectional view of the memory cell 280 along the bit line direction. In a variable resistive element 260, a variable resistor 230 for storing information in accordance with the change of an electric resistance due to electric stress is held between an upper electrode 240 and a lower electrode 250. Anon-linear element 270 is formed on the variable resistive element 260 and has non-linear current-voltage characteristics allowing currents to flow bi-directionally. The memory cell 280 is constituted of a series circuit of the variable resistive element 260 and the non-linear element 270. The non-linear element 270 is a two-terminal element having non-linear current-voltage characteristics wherein a current change to a voltage change is not constant like a diode, etc. In this embodiment, although the non-linear element 270 is formed on the variable resistive element 260, it may be formed under the variable resistive element 260. In addition, the bit line 210 is electrically connected to the non-linear element 270, and the word line 220 is electrically connected to the lower electrode 250 of the variable resistive element 260.

The variable resistive element 260 is a nonvolatile storage element wherein the electric resistance is changed by voltage application, and the electric resistance thus changed is maintained even after canceling the voltage application, thereby making it possible to store data by the change of the resistance. As the variable resistor 230 constituting the variable resistive element 260, as shown in the aforementioned patent document 1, a material of a single crystal or polycrystal perovskite type crystalline structure constituted by lattice matching with the lower electrode 250 is used, wherein more than two kinds of metal elements are contained, and the metal elements are selected from transition metals, alkaline earth metals, and rare earth metals. Further, there are various structures including manganese, titanium, zirconia, and a high-temperature superconducting material. Particularly, manganese oxide obtained by combining the rare earth metals such as La or Pr or a mixed crystal of La and Pr, the alkaline earth metals such as Ca or Sr or a mixed crystal of Ca and Sr, and MnO₃, is particularly effective as the material of the variable resistor. Moreover, the variable resistor 230 with composition of Pr₁₋ₓCaₓMnO₃ (x=0.3, 0.5) has a largest change width of the resistance value, and is frequently used.

The lower electrode 250 has a good lattice matching property with a perovskite type oxide, and Pt having high conductivity and high oxidation resistance is desirable, and a simple substance of a precious metal of a platinum group metals such as Ir, Ph, and Pd or an alloy with the precious metal as a base, or an oxide conductor such as Ir and Ru, or an oxide conductor such as SRO (SrRu₃) and YBCO (YbBa₂Cu₃O₇) can be used. However, a forming temperature of the perovskite type oxide formed on the lower electrode 250 is in a range from 400° C. to 600° C., and the material is exposed to a high oxygen atmosphere, and therefore a selection width of the material is narrowed. The material of the upper electrode 240 is not particularly designated, provided that it is a conductive material and is easy to be worked, and in order to more efficiently manufacture the upper electrode 240, the same material as that of the lower electrode is preferable.

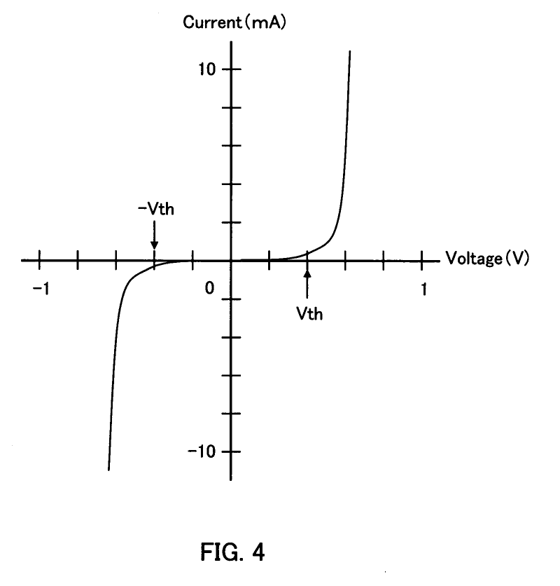

As the non-linear element 270, the device having bi-directionally symmetrical non-linear current-voltage characteristics, as shown in FIG. 4, is preferable, because the currents flow bi-directionally at the time of writing the memory cell 280. As such a device, for example a varistor can be used. The varistor is generally used as an element for protecting an electronic circuit against a power supply surge, and a ZnO varistor prepared by sintering a metal oxide such as zinc oxide (ZnO) and a small amount of bismuth oxide (Bi₂O₃) and a SrTiO₃ varistor are widely known, and the ZnO and the SrTiO₃ varistor are desirable as the non-linear element 270. In addition, since the non-linear element 270 is connected to the variable resistive element 260 in series, the currents necessary for writing of the variable resistive element 260 are flown to the non-linear element 270 at the time of writing. Therefore, the currents whose current density is 30 kA/cm² (programming currents of about 20 μA in an electrode area of 0.8 μm×0.8 μm) or more, as shown in the non-patent document 1, for example, need to be regularly flown. Here, “regularly” means that current characteristics are not changed, or the non-linear element 270 is not destroyed even if turning on/off of the currents is repeated. As shown in FIG. 4, the varistor shows steep switching characteristics that, when the absolute value of the applied voltage applied to the both ends is a certain value (a threshold voltage of the switching characteristics) or less, the currents larger than predetermined minute currents do not flow, and when a predetermined high voltage whose absolute value exceeds the certain value is applied, large currents flow in a direction according to the voltage polarity. Therefore, by optimizing a programming current density in a range not less than 30 kA/cm² and not more than a breakdown current density of the non-linear element 270, the writing of the variable resistive element 260 is possible.

In addition, aluminum and copper wiring is used in the bit line 210 and the word line 220.

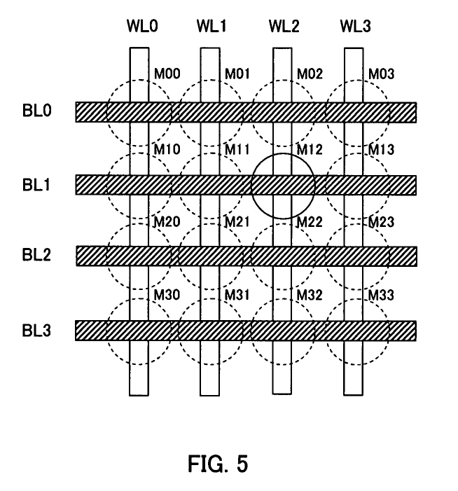

Next, by using the memory cell array of 4×4 structure provided with four bit lines BL0 to BL3 and four word lines WL0 to WL3 as shown in FIG. 5, explanation will be given as to programming, erasing, and reading operation in/from the memory cell and a bias voltage condition of each action for each bit line and word line.

When a programming object is a memory cell M12, a programming voltage Vpp is applied to a selected bit line BL1, ½Vpp is applied to unselected bit lines BL0, BL2, and BL3, Vss(0V) is applied to a selected word line WL2, and ½Vpp is applied to unselected word lines WL0, WL1, and WL3, respectively. As a result, the voltage of Vpp is applied to the both ends of the selected memory cell M12, the voltage of ½Vpp is applied to unselected memory cells M10, M11, M13, M02, M22, and M32 connected to the selected bit line BL1 and the selected word line WL2, and the bias voltage is not applied to the other unselected memory cells.

Similarly, when an erasing object is the memory cell M12, an erasing voltage Vpp is applied to the selected word line WL2, ½Vpp is applied to the unselected word lines WL0, WL1, and WL3, Vss (0V) is applied to the selected bit line BL1, ½Vpp is applied to the unselected bit lines BL0, BL2, and BL3, respectively. As a result, the voltage of −Vpp is applied to the both ends of the selected memory cell M12, the voltage of −½Vpp is applied to the unselected memory cells M10, M11, M13, M02, M22, and M32 connected to the selected bit line BL1 and the selected word line WL2, and the bias voltage is not applied to the other unselected memory cells.

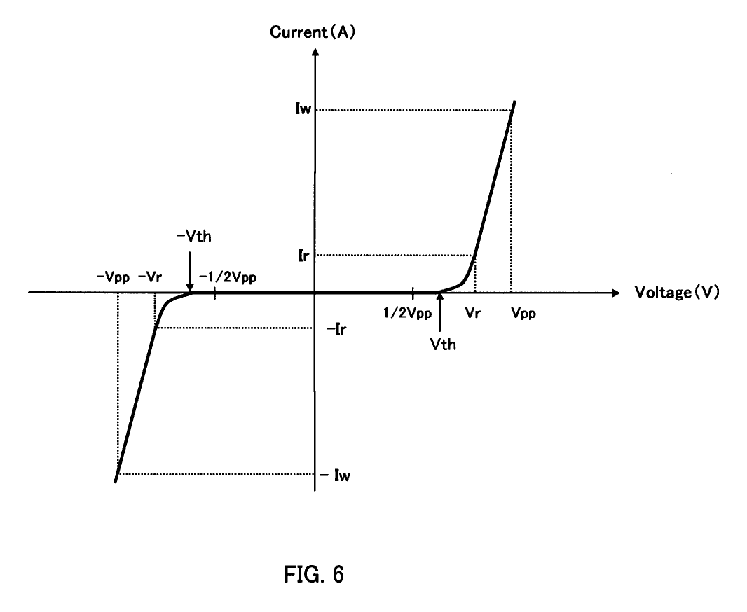

The voltage Vpp applied to the selected memory cell M12 is divided into the variable resistive element 260 and the non-linear element 270. Therefore, the programming voltage Vpp needs to be higher than the programming voltage applied to a simple cross-point type memory cell without the non-linear element 270. Moreover, as shown in FIG. 6, by optimizing a threshold voltage Vth of the non-linear element 270 so that ½Vpp may be lower than the threshold voltage Vth of the switching characteristics of the non-linear element 270, the currents are prevented from flowing to the unselected memory cells to which the voltage of ½Vpp is applied, thus preventing erroneous programming (programming disturbance) to the unselected memory cells, and a power consumption for writing can be entirely reduced.

In a case of erasure also, as shown in FIG. 6, by optimizing the threshold voltage Vth of the non-linear element 270 so that −½Vpp whose absolute value may be lower than the threshold voltage −Vth of a negative voltage side of the switching characteristics of the non-linear element 270, the currents are prevented from flowing to the unselected memory cells to which the voltage of −½Vpp is applied, and erroneous erasure (erasure disturbance) to the unselected memory cells can be prevented, and the power consumption for erasure can be entirely reduced.

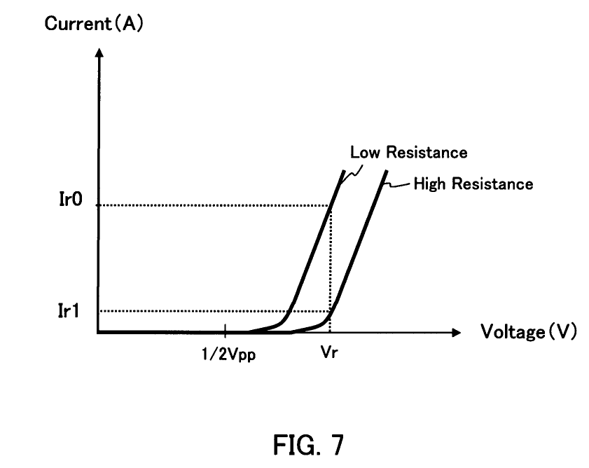

In addition, in a case of a reading action, as shown in FIG. 7, a reading voltage Vr, being a lower voltage than the programming voltage Vpp, is applied to the selected memory cell, and reading is performed by sensing a current Ir0 flowing through the memory cell in a low resistance state and a current Ir1 flowing though the memory cell in a high resistance state. In this case, it is possible to perform reading of data of a plurality of bits at once in a word unit by applying the reading voltage Vr to all of the bit lines BL0 to BL3, Vss(0V) to the selected word line WL2, Vr to the unselected word lines WL0, WL1, and WL3, or in the same way as the programming action, it is possible to perform reading in a memory cell unit by applying the reading voltage Vr to the selected bit line BL1, ½Vr to the unselected bit lines BL0, BL2, and BL3, Vss(0V) to the selected word line WL2, and ½Vr to the unselected word lines WL0, WL1, and WL3, respectively. In a case of the latter, by optimizing the threshold voltage Vth of the non-linear element 270 so that ½Vr may be lower than the threshold voltage Vth of the switching characteristics of the non-linear element 270, the currents are prevented from flowing to the unselected memory cells to which the voltage of ½Vr is applied, and a problem of the parasitic currents in a simple cross-point type array structure, with memory cells constituted of only the variable resistive element 260, is solved. In addition, in a case of the former also, when an array size of the memory cell becomes larger, the voltage causing the parasitic currents is applied to the unselected memory cells due to a voltage distribution on the bit line and the word line caused by a parasitic resistance. etc, of the bit line and the word line. However, by optimizing the threshold voltage Vth of the non-linear element 270 so that this voltage may be lower than the threshold voltage Vth, the array size of the memory cell array can be made larger, and a high integration can be achieved.

Here, when the variable resistive element 260 is in a low resistance state, the voltage of the threshold voltage Vth or more must be applied to the non-linear element 270 to allow the currents of several tens μA to be flown as reading currents. Therefore, a relation as shown in an inequality expression (1) described below is established for the reading voltage Vr.

½Vpp<Vr<Vpp (1)

Here, when the programming voltage Vpp is 5V, the reading voltage Vr is in a range from 2.5 to 5.0V. However, the reading voltage Vr can not be set to be large in consideration of an influence of the reading disturbance, and therefore the reading voltage is set to about 3V.

In addition, when the threshold voltage Vth of the non-linear element 270 is set to 2.0V, the voltage of 3.0V is applied to the variable resistive element 260 of the selected memory cell at the time of programming, and the voltage of 1.0V is applied thereto at the time of reading, respectively. Moreover, the voltage of 0.5V is applied to the variable resistive element 260 of the unselected memory cells to which the voltage of ½Vpp is applied at the time of programming, which is a lower voltage than a voltage value 1.5V applied when there is no non-linear element 270 (Vpp=3.0V). Thus, selectivity is improved even when the threshold voltage is not optimized so that ½Vpp may be lower than the threshold voltage Vth.

As described above in detail, by exchanging the diode of the 1D1R type cross-point type memory cell with the non-linear element such as a varistor allowing the currents to flow bi-directionally, necessary currents can be flown bi-directionally at the time of writing, and even in the variable resistive element with large programming current density, writing is possible. As a result, even in the memory cell array using the variable resistive element with large programming current density, the memory cell array without the transistor as a selected element can be realized, and the selectivity of the memory cell is improved by the switching characteristics of the non-linear element, thus making it possible to manufacture the nonvolatile semiconductor memory device with high density and capable of realizing a high speed access.

### INDUSTRIAL APPLICABILITY

The present invention is applicable to the nonvolatile semiconductor memory device and particularly is suitable for the nonvolatile semiconductor memory device provided with a memory cell array, with a plurality of memory cells constituted of a two-terminal circuit having a variable resistor for storing information in accordance with the change of an electric resistance due to electric stress, arranged in a row direction and in a column direction.

1. A nonvolatile semiconductor memory device comprising:
a memory cell array with a plurality of memory cells arranged in a row direction and in a column direction, each of the memory cells comprising a two-terminal circuit having a variable resistor for storing information in accordance with a change of an electric resistance due to electric stress, wherein
the memory cells have switching characteristics that currents bi-directionally flow according to voltage polarity of a voltage applied to both ends of the memory cells when an absolute value of the voltage exceeds a certain value, and currents larger than predetermined minute currents do not flow when the absolute value of the applied voltage is the certain value or less, and can make currents whose current density is 30 kA/cm² or more flow regularly when a predetermined high voltage whose absolute value exceeds the certain value is applied.

2. The nonvolatile semiconductor memory device according to claim 1, wherein
the memory cell comprises a variable resistive element in which a variable resistor is held between an upper electrode and a lower electrode, and a two-terminal element connected to the variable resistive element in series and having non-linear current-voltage characteristics allowing currents to flow bi-directionally, wherein
the two-terminal element has switching characteristics that currents bi-directionally flow according to voltage polarity of a voltage applied to both ends of the two-terminal element when an absolute value of the voltage exceeds a certain value, and currents larger than predetermined minute currents do not flow when the absolute value of the applied voltage is the certain value or less, and can make currents whose current density is 30 kA/cm² or more flow regularly when a predetermined high voltage whose absolute value exceeds the certain value is applied.

3. The nonvolatile semiconductor memory device according to claim 2, wherein the two-terminal element is a varistor.

4. The nonvolatile semiconductor memory device according to claim 2, wherein the two-terminal element is mainly composed of zinc oxide or SrTiO₃.

5. The nonvolatile semiconductor memory device according to claim 2, wherein
the lower electrode of the plurality of memory cells arranged in the same row is connected to a common word line, the upper electrode of the plurality of memory cells arranged in the same column is connected to a common bit line in the memory cell array, and the nonvolatile semiconductor memory device at least comprising:
a control circuit for controlling programming, erasing, and reading of information into/from the memory cells;
a voltage switch circuit for switching a programming voltage, an erasing voltage, and a reading voltage to be applied to the word line and the bit line; and
a reading circuit for reading the information from the memory cells.

6. The nonvolatile semiconductor memory device according to claim 1, wherein the polarity of the voltage applied to the memory cell is inverted in programming and in erasing.

7. The nonvolatile semiconductor memory device according to claim 1, wherein the variable resistor is a metal oxide having a perovskite type crystalline structure.

8. The nonvolatile semiconductor memory device according to claim 1, wherein the variable resistor is a metal oxide expressed by a general formula, Pr₁₋ₓCaₓMnO₃ (X=0.3, 0.5).
